(19) United States
(12) Patent Application Publication
(10) Pub. No.: US 2026/0194555 A1
(43) Pub. Date: Jul. 9, 2026

(54) METHOD FOR CORRECTING A PROPERTY, IN PARTICULAR SENSITIVITY, OF A CAPACITIVE SENSOR, READING CIRCUIT FOR A CAPACITIVE SENSOR, AND SENSOR SYSTEM

(71) Applicant: Robert Bosch GmbH, Stuttgart (DE)

(72) Inventors: Amin Jemili, Kusterdingen (DE); Christian Marschall, Reutlingen (DE)

(21) Appl. No.: 19/429,316

(22) Filed: Dec. 22, 2025

(30) Foreign Application Priority Data
Jan. 9, 2025 (DE) 10 2025 100 539.7

(51) Int. Cl. G01P 21/00; G01D 18/00; G01P 15/125; H03F 3/45; H04R 1/10

(52) U.S. Cl. CPC G01P 21/00; G01D 18/006; G01P 15/125; H03F 3/4508; H03F 2200/48; H04R 1/1016

(57) ABSTRACT

A method for correcting a sensitivity of a capacitive sensor, in particular accelerometer. The capacitive sensor is configured to generate capacitive sensor signals according to a physical quantity, in particular acceleration, acting on the sensor. In a reading step, a measured value associated with a resting capacitance of the capacitive sensor is read, in particular by means of a reading circuit, and, in a correction step, a correction of the sensitivity of the sensor is performed according to the read measured value of the resting capacitance. A reading circuit for a capacitive sensor and a sensor system configured to perform the method are also described.

### CROSS REFERENCE

The present application claims the benefit under 35 U.S.C. § 119 of Germany Patent Application No. DE 10 2025 100 539.7 filed on Jan. 9, 2025, which is expressly incorporated herein by reference in its entirety.

### FIELD

The present invention relates to a method for correcting a property, in particular sensitivity, of a capacitive sensor, in particular accelerometer, to a reading circuit for such a capacitive sensor, and to a sensor system in which such a capacitive sensor and such a reading circuit are integrated.

### BACKGROUND INFORMATION

In-ear headphones or earphones are worn directly in the ear and are typically wirelessly connected to a portable device, such as a smartphone, a smartwatch, or the like. Sensors can be integrated into the in-ear headphone. For example, microphones may be provided which capture voice signals from the user. Furthermore, inertial sensors or accelerometers may be provided which sense interaction of the user with the in-ear headphone. For example, an accelerometer may be provided in order to detect, in particular haptically, certain gestures with which the user controls the in-ear headphone. Thus the user can tap on the in-ear headphone once or twice with their finger in order to activate or deactivate certain functions. Such gestures are also referred to as tap or double-tap interaction. For example, such a gesture may pause the playback of music, select the next song, or adjust the volume.

Furthermore, a particularly high-bandwidth accelerometer may be provided which is integrated into the in-ear headphone to measure body-borne sound. Such an accelerometer is also referred to as an acoustic accelerometer. The body-borne sound is generated by the user's vocal cords and conducted to the in-ear headphone via the user's body and can be sensed there by the acoustic accelerometer.

The acoustic path extending from the user's vocal cords to the in-ear headphone is, in a first approximation, unaffected by external noise influences, which may occur, for example, when a nearby person speaks loudly. This advantageous characteristic, according to which primarily the body-borne sound generated by the wearer of the in-ear headphone themself is sensed via the acoustic path, can be used to suppress ambient noises during telephone calls and thus can contribute to active noise reduction.

Stable sensitivity of the accelerometers is desirable for the algorithmic further processing of the body-borne sound signal. As a result of excessive sensitivity, however, the useful signal can in particular prematurely hit the limit and be non-linearly distorted, in which case relevant information can be lost. Reduced sensitivity may result in the signal-to-noise ratio decreasing and/or the useful signal of the body-borne sound being less easily extracted.

Since accelerometers are designed in particular for performance, bandwidth, and noise optimization, in practical implementation there are typically disadvantages, in particular for the sensitivity stability and/or sensitivity drift of the accelerometer as a result of, in particular, soldering stress occurring during the installation of the accelerometer in a terminal device and/or aging effects over the lifetime of the accelerometer.

### SUMMARY

An object of the present invention is to provide a method for correcting a property, in particular sensitivity, of a capacitive sensor, said method making it possible to compensate for disturbance variables which occur during operation of the sensor or during the installation of the sensor in a terminal device.

The aforementioned object may be achieved by certain features of the present invention. Advantageous configurations of the present invention are disclosed herein. According to an aspect of the method-related configuration of the present invention, in order to correct the property, in particular sensitivity, of a capacitive sensor which, during operation, generates capacitive sensor signals according to a physical quantity, in particular acceleration, acting on the sensor, it is proposed that, in a reading step, a measured value associated with a resting capacitance of the capacitive sensor is read, in particular by means of a reading circuit. In a subsequent correction step, a correction of the property, in particular sensitivity, of the sensor is performed according to the read measured value of the resting capacitance. Thus it is basically proposed that the correlation between a change in the resting capacitance and an associated property, in particular sensitivity, of the sensor be utilized in order to compensate for the influence of disturbance variables. The resting capacitance of the sensor can be measured at any given times, in particular after the sensor has been installed in a terminal device for operation as intended. This enables compensation for disturbance variables, in particular over the entire life cycle of the sensor. The correction of the property, in particular sensitivity, of the sensor according to the measured value of the resting capacitance which has been read in the reading step comprises in particular a correction of the sensor signals provided by the sensor to form corrected sensor output signals.

According to a further aspect of the present invention, a reading circuit for a capacitive sensor is provided, the reading circuit being configured to read the measured value associated with the resting capacitance of the capacitive sensor, on the basis of capacitive sensor signals provided by the sensor, and to provide said measured value for correcting the property, in particular sensitivity, of the sensor according to the read measured value of the resting capacitance. The reading circuit is preferably used in the method for correcting the property, in particular sensitivity, of the sensor to determine the measured value of the resting capacitance on the basis of the sensor signals provided by the sensor.

According to a further aspect of the present invention, a sensor system is provided which is configured to implement the methods of the present invention described above as an integrated system. For this purpose, according to an example embodiment of the present invention, the sensor system comprises the capacitive sensor, which is configured to generate the capacitive sensor signals according to the physical quantity, in particular acceleration, acting on the sensor, and an integrated circuit. The integrated circuit comprises the reading circuit for reading a measured value associated with the resting capacitance of the capacitive sensor and a correction circuit for correcting the sensitivity of the sensor according to the read measured value of the resting capacitance. The sensor system is implemented as an integrated component having a capacitive sensor system and having an integrated circuit, in particular reading circuit.

In a preferred configuration of the present invention, the capacitive sensor is an accelerometer, but, in addition to such accelerometers, in principle any other technical implementations which operate according to an analog capacitive sensor principle, in particular differential capacitance principle, are also possible. The capacitive sensor comprises, in possible embodiments, at least one capacitive element. Preferably a plurality of capacitive elements are provided. The resting capacitance of a sensor having multiple capacitive elements corresponds in particular to the sum capacitance of the capacitive elements. The correction of the property, in particular sensitivity, of the sensor can, in configurations, be made by means of an analog or digital correction circuit.

The correction of the property, in particular sensitivity, of the sensor in the correction step can be made in particular according to a comparison of the read measured value with a reference value of the resting capacitance. The reference value may be specified, for example, by a sensor-type-specific value of the resting capacitance.

In a preferred configuration of the present invention, in a calibration step occurring before the reading step the reference value of the resting capacitance of the capacitive sensor is determined in particular by means of the reading circuit and in the correction step the property, in particular sensitivity, of the sensor is corrected according to a change in the read measured value of the resting capacitance with respect to the reference value. The use of a reading circuit integrated in the sensor or in the sensor system has the advantage in particular that the reference value of the resting capacitance can be determined by individual measurement in a component-specific manner and, correspondingly, a component-specific correction, in particular for subsequently occurring disturbance variables, is enabled in the correction step. Thus, in a preferred configuration the correction of the property of the sensor is made in light of the individual sensor characteristic.

The reading of the resting capacitance and the correction of the sensitivity according to the read measured value of the resting capacitance can in principle take place at any specified or specifiable times over the life cycle of the sensor. The reading step and the correction step are preferably repeated as a group over the lifetime of the sensor, in particular repeatedly carried out at periodically recurring time intervals, in order to ensure a preferably improved sensitivity of the sensor over its lifetime.

In an advantageous configuration of the present invention, a threshold value check of the change in the resting capacitance takes place in the correction step, in particular to perform an automatic sensitivity correction when the resting capacitance of the sensor is sensed or read at recurring time intervals. For this purpose, the change in the resting capacitance can be determined in particular on the basis of the deviation of the read measured value from the reference value and stored in a rewritable data store of the correction circuit.

In an advantageous configuration of the method, a structural parameter, in particular component- or type-specific structural parameter, is taken into account in the correction of the property, in particular sensitivity, in the correction step. The structural parameter can be ascertained as a correlation between the change in the property, in particular sensitivity, of the sensor and the change in the resting capacitance of the sensor. Such a correlation can in particular be ascertained experimentally, in which case preferably a statistically relevant number of sensors, in particular as representatives of a sensor type of specified design, are placed under the influence of a disturbance variable or a stress in a controlled way. The structural parameter to be taken into account in the correction step is stored, in possible embodiments, as a component- or type-specific reference in a data store of the correction circuit.

Preferably, the structural parameter, and/or the reference value determined in the calibration step, in particular as a component-specific reference of the resting capacitance of the sensor, is stored in a data store of the correction circuit. The correction of the property, in particular sensitivity, of the sensor according to the measured value of the resting capacitance read in the reading step comprises, in possible embodiment examples, a correction, preferably digital correction, of the sensor signals provided by the sensor to form corrected sensor output signals from which, for example, the influence of, in particular, a subsequently occurring disturbance variable has been eliminated. The structural parameter, and/or the reference value of the resting capacitance determined in the calibration step, will preferably be taken into account in the correction step in the correction of the property, in particular sensitivity. The correction of the property, in particular sensitivity, of the sensor can be made, for example, according to a deviation of the read measured value from the reference value of the resting capacitance.

The reading step and the correction step take place preferably after the sensor has been put into operation, in particular to compensate for a disturbance variable occurring during the lifetime of the sensor. The calibration step takes place preferably before the final installation of the sensor in a terminal device, for example at the end of the production of the sensor in a measuring and trimming step.

In one possible example embodiment of the present invention, the reading circuit comprises a closed control loop.

The reading circuit comprises, in a preferred configuration of the present invention,
a differential amplifier having at least two common-mode inputs for superposing sensor signals of the sensor in common mode and at least one further input for receiving a reference signal;
a measuring device, which is connected to the output side of the differential amplifier, for measuring the measured value of the resting capacitance,
at least one coupling capacitor for coupling the reading circuit back to the sensor.

In a preferred configuration of the sensor system of the present invention, the sensor comprises at least two capacitive sensor elements, wherein each capacitive sensor element is configured to generate a capacitive sensor signal according to a physical quantity, in particular acceleration, acting on the sensor, wherein, in the reading step, at least a first sensor signal, which is associated with a first capacitive sensor element, and a second sensor signal, which is associated with a second capacitive element, are superposed in common mode.

According to an example embodiment of the present invention, the sensor system is preferably configured as an integrated system for performing the presented method for correcting the property, in particular sensitivity, of the capacitive sensor.

The benefits and advantages described in the context of this disclosure apply in particular to electronic components in the field of entertainment electronics, but are not limited to this field of application. In particular, the method of the present invention presented here and the reading circuit of the present invention configured for this purpose may be used in capacitive sensors in general. Further details and advantages of the present invention will be explained in more detail in the following with reference to the embodiment examples shown in the figures, wherein a sensitivity correction of the sensor is discussed by way of example and in a non-limiting manner. Of course, the core ideas may be implemented more generally to correct any property of the sensor, for example in the context of a calibration, sensitivity correction and/or error correction and/or other disturbance-variable compensation.

### BRIEF DESCRIPTION OF THE DRAWINGS

FIG. 1 shows a capacitive sensor according to a possible embodiment example of the present invention in a resting position, in a schematic sectional illustration.

FIG. 2 shows the capacitive sensor of FIG. 1 under the effect of an acceleration, in a schematic sectional illustration.

FIG. 3 shows the capacitive sensor of FIG. 1 under the effect of a stress-related disturbance variable, in a schematic sectional illustration.

FIG. 4 shows the correlation between a change in the sensitivity and the changed resting capacitance, in a schematic graph.

FIG. 5 shows a method for correcting the sensitivity according to an example embodiment of the present invention, in a schematic block diagram.

FIG. 6 shows a schematic circuit diagram of a sensor system having a reading circuit configured to read the resting capacitance of the sensor, according to an example embodiment of the present invention.

FIG. 7 shows a graph of signals provided for reading the resting capacitance.

FIG. 8 shows a control equivalent circuit diagram of FIG. 6.

Identical or corresponding elements are provided with the same reference signs in all figures.

### DETAILED DESCRIPTION OF EXAMPLE EMBODIMENTS

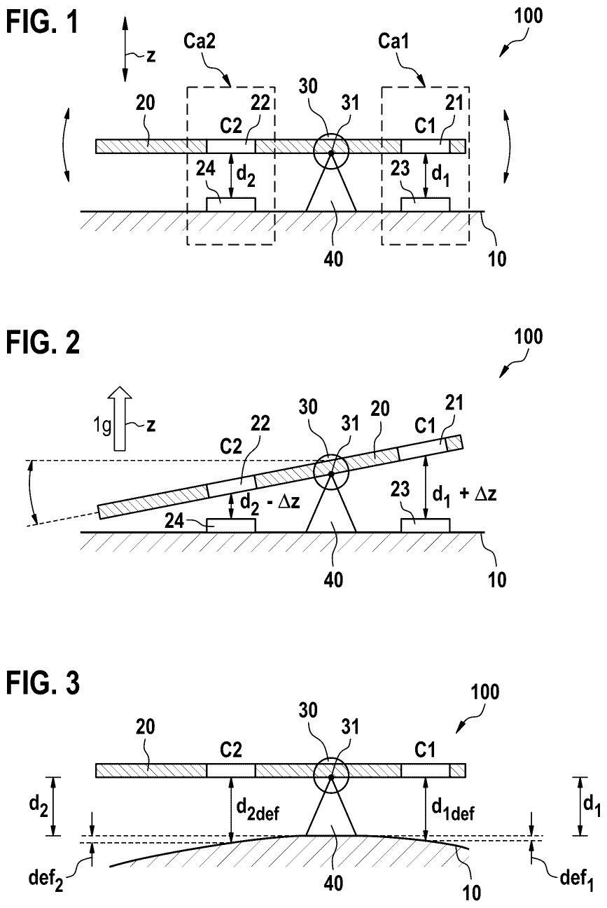

FIGS. 1 to 3 schematically show a capacitive sensor 100 according to one possible embodiment. The sensor 100 shown may be used, for example, as an accelerometer in an in-ear application. In the embodiment example shown, a mass element 20 (also: seismic mass) of the capacitive sensor 100 is formed by a microelectromechanical structure in the form of an asymmetric rocker.

The capacitive sensor 100 shown in cross-section in FIG. 1 is designed to detect an acceleration oriented perpendicularly to a wafer or to a planar substrate 10 (z-direction) and to determine a variable corresponding to the acceleration. For this purpose, the mass element 20, which is configured as an asymmetric rocker, is movably, in particular pivotably, mounted above the substrate 10. For example, the mass element 20 may be connected to an anchor 40 by means of a spring element 30, the anchor being fixedly arranged on the substrate 10. The mass element 20 is movable about a pivot axis 31 of the spring element 30, the pivot axis 31 of the spring element 30 extending perpendicularly to the drawing plane of the illustration.

The mass element 20 comprises upper electrodes 21, 22 arranged on opposite sides of the pivot axis 31. In the illustrated embodiment example, the mass distribution of the mass element 20 is asymmetric with respect to the pivot axis 31. This may be achieved, as shown in particular in the illustrated embodiment example, by suspending the mass element 20 on the anchor 40 at an offset with respect to the center of mass. Alternatively or additionally, an additional mass may be provided on the mass element 20.

The counter electrodes in the form of lower electrodes 23, 24 are fixedly attached to the substrate 10. The electrode pair of the first upper electrode 21 and the first lower electrode 23 forms a first capacitive element Ca1 having a first capacitance C1 which varies according to acceleration acting on the sensor 100. Correspondingly, the electrode pair of the second upper electrode 22 and the second lower electrode 24 forms a second capacitive element Ca2 having a second capacitance C2 which varies according to acceleration acting on the sensor 100. The capacitances C1, C2 of the capacitive elements Ca1, Ca2 vary according to the acceleration acting on the sensor 100. To output the sensor signals reflecting the magnitude of the acting acceleration, the capacitive elements Ca1, Ca2 are connected to sensor lines.

The sensor principle of the capacitive sensor 100 is thus based on a spring-mass system in which the upper electrodes 21, 22 movably mounted by means of the mass element 20 form capacitive elements C1, C2 having variable capacitances together with the lower electrodes 23 and 24 fixed to the substrate 10. The lower electrodes 23, 24 are arranged with respect to the upper electrodes 21 and 22 of the mass element 20 such that the magnitude of the acceleration acting on the sensor 100 can be ascertained by evaluating a first capacitance C1 and the second capacitance C2. In particular, a difference signal C2-C1 associated with the difference between the first and second capacitances C1, C2 may be generated and evaluated for this purpose.

FIG. 2 shows a cross-section through the sensor 100 in order to illustrate how it functions. If the sensor 100 experiences an acceleration in the z-direction Z as shown in FIG. 2, a force directed toward the substrate 10 acts on the second upper electrode 22 due to the asymmetric suspension. Due to this acceleration, the seismic mass 20 in the form of a rocker is moved about the pivot axis 31 such that a first distance d1 between the first upper electrode 21 and the first lower electrode 23 increases and a second mean distance d2 between the second upper electrode 22 and the second lower electrode 24 decreases. In other words, in the event of an acting acceleration, one rocker side is lowered and at the same time the other rocker side of the asymmetric rocker is raised. The thereby changing electrode distances d1 and d2 result in changes in the first capacitance C1 of the first capacitive element C1 and in the second capacitance C2 of the second capacitive element Ca2. In particular, an acting acceleration results in a change in the capacitive difference signal C2-C1 according to, preferably proportional to, the acting acceleration. The principle of operation of such sensor structures can thus be based on the measurement of the capacitive difference signal C2-C1 given by the first and second capacitances C1, C2 of the capacitive elements Ca1, Ca2 described above.

The resting capacitance C0 which exists in the resting position in FIG. 1, i.e. without the action of an external physical quantity, in particular acceleration, in the equilibrium position, is given by the sensor sum capacitance. The resting capacitance C0 of the capacitive sensor 100 can thus be determined by the relationship

$$C 0 = \frac{C 1 + C 2}{2} \qquad ( 1 )$$

A measure of the sensitivity of the sensor 100 can be provided by, for example, the capacitance change dC in comparison with the equilibrium position in the case of an acceleration of 1 g acting on the sensor 100. In the case of a deflection of the mass element 20 as a result of gravitational acceleration (1 g), the capacitive difference signal dC(1 g) is approximately:

$$d C ( 1 g ) \approx ε A \frac{Δ z}{{d}^{2}} \qquad ( 2 )$$

Here, ε indicates the permittivity, A indicates the effective area of the capacitive elements Ca1, Ca2, d indicates the electrode distance, and Δz indicates the deflection from the resting position (cf. in particular FIG. 1).

The lateral extent of the micromechanical structure may be comparatively large, depending on the design. Accordingly, the electrode distance d of the upper electrodes 21, 22 from the lower electrodes 23, 24 may be comparatively small, depending on the design. In the case of such a structural design of the sensor 100, small stress-related movements of the lower electrodes 23, 24, which are arranged opposite the mass element 20 on the substrate 10, result in a sharp change in sensitivity.

FIG. 3 schematically shows a situation, provided by way of example, in which the substrate 10 has been spherically curved under the influence of forces occurring, in particular stress. Such deformation can result in a symmetric change def1 and def2 in the electrode distances d1 and d2:

$${d}_{d e f} = {d}_{1 def} = {d}_{1} + d e {f}_{1} = {d}_{2 d e f} = {d}_{2} + d e {f}_{2} \qquad ( 3 )$$

It can be assumed approximately that, under the influence of such a disturbance variable, the resting capacitance changes proportionally to the change in the electrode distances d as follows:

$$C {0}_{Stress} = \frac{C 1 + C 2}{2} \frac{{d}_{d e f}}{d} \qquad ( 4 )$$

Under the influence of such a disturbance variable, a square dependence of the sensitivity dC_{Stress} (1 g) results, which can be attributed to symmetric change in the electrode distances d_{def}:

$$d {C}_{Stress} ( 1 g ) \approx ε A \frac{Δ z}{{d}_{d e f}^{2}} = ε A \frac{Δ z}{( {d}_{1} + d e {f}_{1} ) ( {d}_{2} + d e {f}_{2} )} \qquad ( 5 )$$

wherein dC_{Stress} (1 g) indicates the sensitivity of the sensor 100 under the influence of a disturbance variable (stress) in the case of an acting acceleration of 1 g (gravitational acceleration).

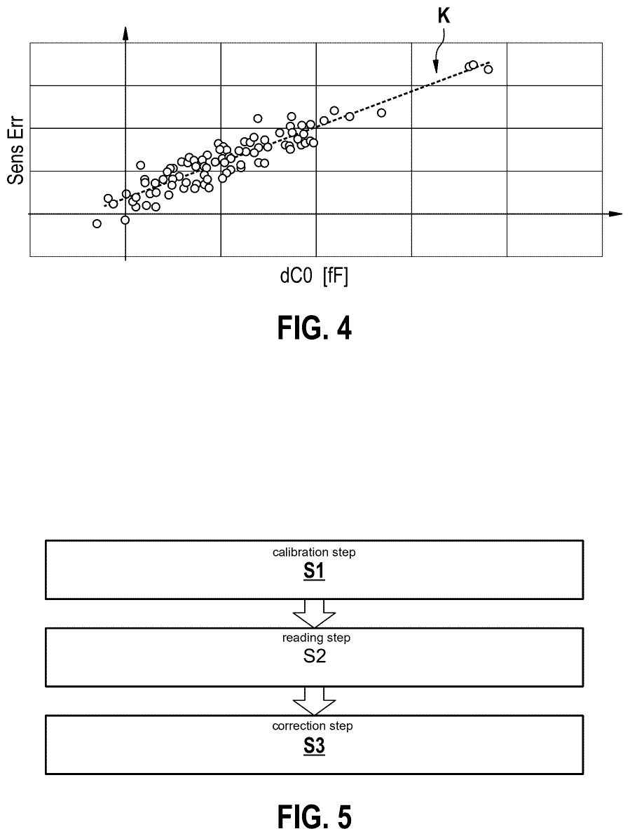

FIG. 4 illustrates the correlation between a sensor error (SensErr), associated with the sensitivity of the sensor 100, and changes in the resting capacitance dC0. It shows measured values of the change in the resting capacitance dC0 of sensors 100 of the same design after these sensors 100 have been subjected to stress paths of different intensity. The measured values shown by way of example arise from a single stress path, but may also arise from different stress paths. On the basis of the correlation, it is possible to determine, in particular, a type-specific structural parameter β which describes the correlation between the sensitivity of the sensor and the resting capacitance change. For this purpose, in particular a linear approximation may be made; in particular, the structural parameter β may be determined from the slope of the correlation line K.

It is proposed that the correlation, shown in FIG. 4, between the sensitivity change and the resting capacitance change dC0 be used as the basis of a compensation and reset of the changed sensitivity dC_{Stress} of the sensor 100. By using a measurement to determine a measured value C0ₘ of the resting capacitance C0 of the sensor in a reading step, this compensation is possible at any given times during the lifetime of the sensor.

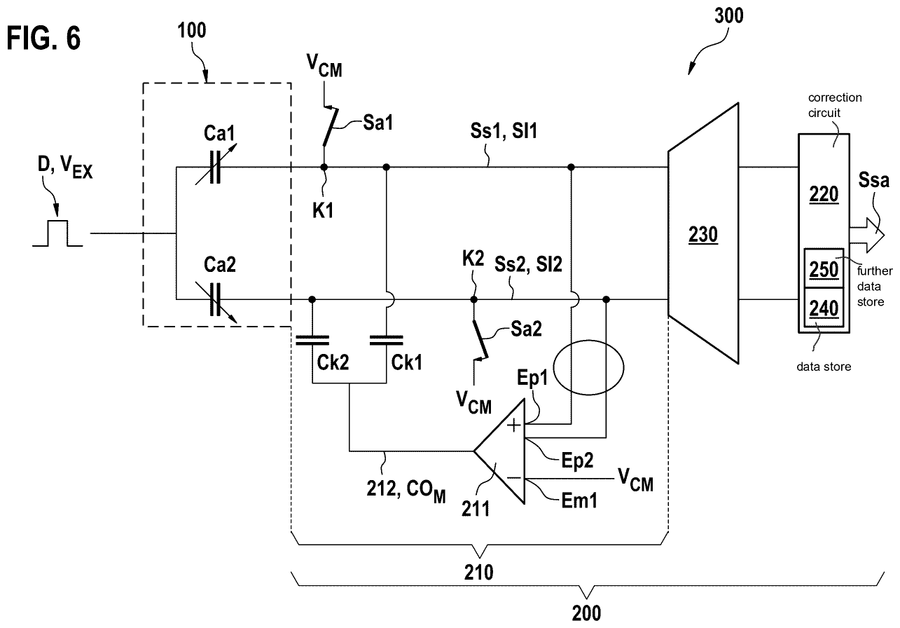

FIG. 5 illustrates a method for correcting the sensitivity of the sensor 100 according to an exemplary configuration, wherein in a calibration step S1 a reference value C0_{ref} of the resting capacitance, in particular sum capacitance, of the capacitive sensor 100 is determined, in particular by means of a reading circuit 210 shown in more detail in FIG. 6. In a reading step S2, a measured value C0ₘ associated with the resting capacitance C0 of the capacitive sensor 100 is read by means of the reading circuit 210. In a subsequent correction step S3, a correction of the sensitivity of the sensor 100 is performed according to the read measured value C0ₘ of the resting capacitance C0. In the correction step S3, the correction of the sensitivity of the sensor 100 can be made in particular according to a change in the resting capacitance dC0 with respect to the reference value C0_{ref} determined in the calibration step S1, according to the relationship dC0=(C0_{ref}−C0).

The calibration step S1 preferably takes place as part of a sensor trimming at the end of the manufacturing of the sensor 100, and in the calibration step S1 the sensor 100 is further preferably calibrated in the combination of the sensor system 300. For this purpose, for example a sensitivity calibration of the sensor 100 can be carried out according to a first sensitivity dC(1 g) of the sensor 100, which can be ascertained in particular on the basis of the capacitive difference signal dC(1 g) in the case of an acceleration of 1 g acting on the sensor 100. In the calibration step S1, the reference value C0_{ref} for the resting capacitance and the structural parameter β are stored in a data store 240, in particular non-volatile data store 240 (cf. in particular FIG. 6), of the correction circuit, so that this resting capacitance can be offset against the measured value C0ₘ of the resting capacitance C0 which is read in correction step S3, in particular to detect a sensitivity drift of the sensor 100. Optionally, the change in the sensitivity dC(1 g), dC_{Stress} (1 g), can be stored in a further data store 250, in particular rewritable data store 250 (cf. in particular FIG. 6).

After the sensitivity calibration of the sensor 100 in the calibration step S1, typically a final installation of the sensor 100 and/or the sensor system 300 in a terminal device, for example in a headphone, takes place and the sensor 100 is subsequently put into operation. This can in general cause a change in the sensitivity dC(1 g) of the sensor 100 due to soldering stress and/or aging effects and/or environmental influences such as moisture, such that in the reading step S2 there is typically a changed sensitivity dC_{Stress} (1 g) of the sensor 100.

In the correction step S3, the reference value C0_{ref} stored in the sensor system 300, which reference value was ascertained in the calibration step S1, is offset against the current measurement of the preceding reading step S2. In this way, the change in the resting capacitance dC0 since the sensitivity calibration can be determined. The sensitivity changed due to stress, dC_{Stress} (1 g), can be ascertained for example by means of the relationships

$$d {C}_{S t r e s s} ( 1 g ) ∼ dC ( 1 g ) \cdot dC 0$$

$$d {C}_{S t r e s s} ( 1 g ) = dC ( 1 g ) \cdot dC 0 β$$

In order to compensate, in the correction step S3, for the sensitivity changes of the sensor which can occur after soldering or after any other form of lifetime stress (e.g. moisture-induced curvature), the change in the resting capacitance dC0 is adjusted by the application of the component- or assembly-specific proportionality factor β and thus the change in the sensitivity is determined.

This is done by utilizing the correlation, shown in FIG. 4, between the sensitivity change and the change in the resting capacitance C0, which is also theoretically demonstrated by the equations (4) and (5). By using a measurement to ascertain the resting capacitance C0 of the sensor, this compensation is possible at any given times during the lifetime of the sensor. The proportionality factor is specified by a structural parameter β, which can be ascertained experimentally by means of corresponding measurements (FIG. 4). For example, the structural parameter β may be experimentally ascertained individually for certain assemblies.

This change in the regular sensitivity is set by means of the correction circuit, preferably by means of a digital correction circuit in the sensor 100, and is directly eliminated from the sensor signals provided by the sensor. As a result of this procedure, the impairment of the sensitivity of the sensor 100 due to disturbance variables that occur during the lifetime of the sensor 100 can be reduced, so that the sensor 100 can preferably permanently perform its function.

The reading of the changed resting capacitance with subsequent correction of the sensitivity can be performed at any given times, in particular at user-specified or user-specifiable times, using the reference value C_{ref} and the structural parameter β. In a possible embodiment example, the reading step and the correction step are repeatedly carried out in a group over the lifetime of the sensor 100, in particular are repeatedly carried out in a group at periodically recurring time intervals. Optionally, a threshold value check of the change in the resting capacitance dC0 can take place in the correction step S3, which threshold value check can in particular serve as the trigger of an automatic sensitivity correction in the sense that a correction of the sensitivity takes place only if the change in the resting capacitance dC0 is greater than a specified or specifiable threshold value. This threshold value can be stored in a data store 240, in particular non-volatile data store 240 (cf. in particular FIG. 6), of the correction circuit during the calibration step S1.

FIG. 6 shows a schematic illustration of a sensor system 300 having a capacitive sensor 100, and an integrated circuit 200 which includes a reading circuit 210 for reading out a measured value Cₘ of the resting capacitance C0 of the capacitive sensor 100 and a correction circuit 220 for correcting the sensitivity of the sensor 100 accordingly. In the example shown exemplarily, the sensor 100 comprises the two capacitive sensor elements Ca1, Ca2, each capacitive sensor element Ca1, Ca2 being configured to generate a capacitive sensor signal Ss1, Ss2 according to a physical quantity, in particular acceleration, acting on the sensor 100. For this purpose, the first capacitive sensor element Ca1 is connected to a first sensor line SI1 and the second capacitive sensor element Ca2 is connected to a second sensor line SI2. To amplify and digitize the sensor signals Ss1, Ss2 provided by the sensor 100, an amplifier stage 230 with analog-to-digital converter and the correction circuit 220 for correcting the sensitivity of the sensor 100 are provided on the output side, so that corrected sensor output signals Ssa can be generated on the basis of the sensor signals during operation of the sensor 100.

The reading circuit 210 also comprises a differential amplifier 211 having two common-mode inputs Ep1, Ep2 and one further input Em1. The first sensor line SI1 is connected to the first common-mode input Ep1 and the second sensor line SI2 is connected to the second common-mode input Ep2. The reading circuit 210 is coupled back to the first and second sensor lines SI1, SI2 by means of a first and a second coupling capacitor Ck1, Ck2, respectively, so that the reading circuit 210 forms a control circuit for measuring the measured value C0ₘ, which is associated with the resting capacitance C0. The first and second coupling capacitors Ck1, Ck2 each have a capacitance C_{cm}. The differential amplifier 211 is in particular configured to superpose, in common mode, signals which are fed into the first common-mode input Ep1 and into the second common-mode input Ep2 and to amplify the difference of the superposed signal from a reference signal V_{cm}, in particular reference voltage, which is provided via the input Em1. The reference signal V_{cm} is in particular a reference level which is specified within the circuit. The reference signal V_{cm} can be fed into the first sensor line SI1 and the second sensor line SI2 via a first switch Sa1 and a second switch Sa2, respectively. In the equilibrium state of the differential amplifier 211, due to the back-coupling by means of the coupling capacitors Ck1, Ck2 having capacitance C_{cm}, an output signal V_{ASIC} generated at the output of the differential amplifier 211 is proportional to the resting capacitance C0 (sum capacitance) of the sensor 100 and can thus be used to capture the measured value C0ₘ of the resting capacitance C0 in the calibration step S1 and/or in the reading step S2.

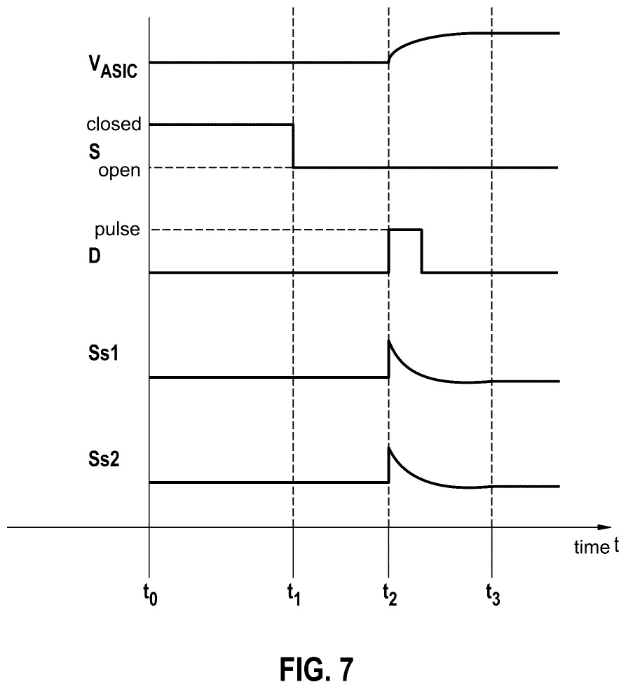

FIG. 7 illustrates the signal structure for reading the measured value Com for the resting capacitance C0.

At a first time to, the switches Sa1, Sa2 become closed (illustrated by the signal curve of the signal S) and the nodes K1, K2 or the common-mode inputs Ep1, Ep2 are initialized according to the reference signal V_{cm}. After the switches Sa1, Sa2 have been opened at a second time t₁, the nodes K1, K2 are initialized by means of a common-mode pulse D at a third time t₂ according to an external voltage V_{EX}. As a result, a charge Q_{c} (=V_{EX} C0) is fed to nodes K1, K2 so that in-phase first and second sensor signals Ss1, Ss2 are present at the common-mode inputs Ep1, Ep2 of the differential amplifier 211 and a differential input voltage of (0.5*V_{Ss1}+0.5*V_{Ss2})−V_{CM}, corresponding to the sensor signals Ss1, Ss2 and the reference signal V_{CM}, is present at the differential amplifier 211. The voltage jump is registered by the differential amplifier 211, and therefore the differential amplifier controls the output signal V_{ASIC} accordingly to restore the equilibrium. For this purpose, charge Q_{CM} (=V_{ASIC} C_{cm}) is applied. The output signal V_{ASIC} is measured at a third time t3 in the equilibrium state of the differential amplifier 211 by means of a measuring device 212. In the equilibrium state of the differential amplifier 211, the following applies:

$${Q}_{C} = {Q}_{CM}$$

$${V}_{EX} C 0 = {V}_{ASIC} {C}_{CM}$$

With C_{CM} and V_{EX} known, the resting capacitance C0 thus can be exactly determined on the basis of the measured output signal V_{ASIC} and, as described above, can be used to correct the sensitivity.

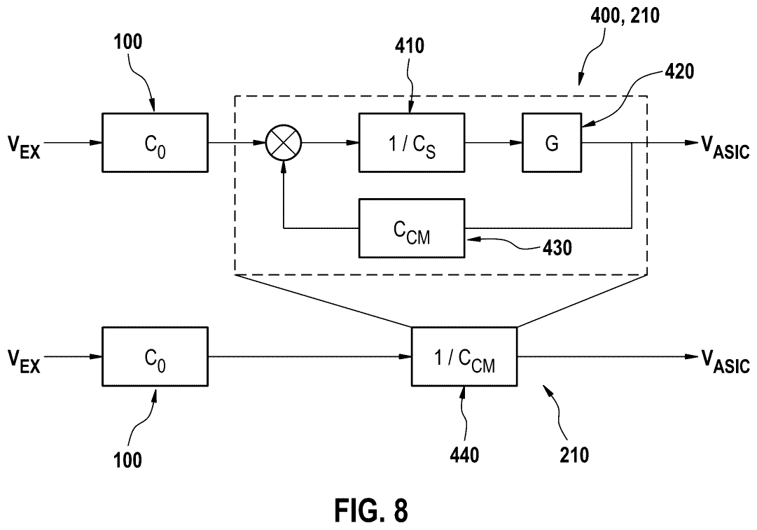

FIG. 8 shows a control equivalent circuit diagram of the reading circuit 210 (cf. in particular FIG. 6).

To sense the resting capacitance C0, a control loop 400 comprises a controlled system having a first control element 410, which is determined by a total sum capacitance 1/C_{S} of the capacitive elements Ca1, Ca2 and of the coupling capacitors Ck1, Ck2 according to C_{S}=C0+C_{CM}. The differential amplifier 211 corresponds to a second control element 420 having a gain G. The feedback 430 corresponds to the coupling capacitors Ck1, Ck2 having capacitance C_{CM}. Thus, for the closed control loop 400, the following applies to the closing condition

$$\frac{( 1 / {C}_{s} ) G}{1 + ( 1 / {C}_{s} ) G {C}_{C M}}$$

in the limiting case of large gain (G→∞):

$$\frac{( 1 / {C}_{s} ) G}{1 + ( 1 / {C}_{s} ) G {C}_{C M}} \to ( \frac{1}{{C}_{C M}} ) .$$

The control loop 400 can therefore, as shown in FIG. 8, be described in an equivalent circuit diagram by a single control element 440, which is specified by the capacitance C_{CM}.

What is claimed is:

1. A method for correcting a sensitivity of a capacitive sensor, wherein the capacitive sensor is configured to generate capacitive sensor signals according to a physical quantity acting on the capacitive sensor, the method comprising:
in a reading step, reading out a measured value associated with a resting capacitance of the capacitive sensor; and
in a correction step, performing a correction of the sensitivity of the capacitive sensor according to the read measured value of the resting capacitance.

2. The method according to claim 1, wherein the capacitive sensor is an accelerometer, and the physical quantity is acceleration.

3. The method according to claim 1, wherein, in a calibration step occurring before the reading step, a reference value of the resting capacitance of the capacitive sensor is determined, wherein, in the correction step, the sensitivity of the capacitive sensor is corrected according to a change in the resting capacitance with respect to the reference value.

4. The method according to claim 1, wherein the reading step and the correction step are repeated as a group over a lifetime of the capacitive sensor, the reading step and the correction step being repeatedly carried out at periodically recurring time intervals.

5. The method according to claim 3, wherein a structural parameter is taken into account in the correction of the sensitivity of the capacitive sensor in the correction step, wherein the structural parameter is ascertained experimentally as a correlation between a change in the sensitivity of the capacitive sensor and the change in the resting capacitance of the capacitive sensor.

6. The method according to claim 1, wherein a threshold value check of a change in the resting capacitance takes place in the correction step.

7. The method according to claim 5, wherein: (i) the structural parameter and/or the reference value of the resting capacitance determined in the calibration step, is stored, and/or (ii) the structural parameter and/or the reference value of the resting capacitance determined in the calibration step, are taken into account in the correction step in the correction of the sensitivity of the senso.

8. The method according to claim 1, wherein: (i) the correction step takes place after the capacitive sensor has been put into operation, to compensate for a disturbance variable occurring during a lifetime of the capacitive sensor, and/or (ii) the calibration step takes place before a final installation of the capacitive sensor in a terminal device.

9. The method according to claim 1, wherein the capacitive sensor includes at least two capacitive sensor elements, wherein each capacitive sensor element of the at least two capacitive sensor elements is configured to generate a capacitive sensor signal according to a physical quantity acting on the sensor, wherein, in the reading step for reading the resting capacitance, at least a first sensor signal, which is associated with a first capacitive sensor element of thee at least two capacitive elements, and a second sensor signal, which is associated with a second capacitive element of the at least two capacitive sensor elements, are superposed in common mode and read.

10. The method according to claim 9, wherein the resting capacitance corresponds to a sum capacitance of the at least two capacitive elements of the capacitive sensor.

11. A reading circuit for a capacitive sensor, the reading circuit being configured to:
read a measured value associated with a resting capacitance of the capacitive sensor, based on capacitive sensor signals provided by the capacitive sensor; and
provide the measured value for correcting a sensitivity of the capacitive sensor according to the read measured value of the resting capacitance.

12. The reading circuit according to claim 10, comprising:
a differential amplifier having at least two common-mode inputs for superposing sensor signals of the capacitive sensor, and at least one further input for receiving a reference signal;
a measuring device, which is connected to an output side of the differential amplifier, the measuring device configured to measure the measured value of the resting capacitance; and
at least one coupling capacitor configured to couple the reading circuit back to the capacitive sensor.

13. A sensor system, comprising:
a capacitive sensor; and
an integrated circuit;
wherein the capacitive sensor is configured to generate capacitive sensor signals according to a physical quantity, acting on the capacitive sensor, wherein the integrated circuit includes a reading circuit configured to read a measured value associated with a resting capacitance of the capacitive sensor and a correction circuit configured to correct a sensitivity, of the capacitive sensor according to the read measured value of the resting capacitance.
